(19) United States
(12) Patent Application Publication
(10) Pub. No.: US 2011/0298052 A1
(43) Pub. Date: Dec. 8, 2011

(54) Vertical Stacking of Field Effect Transistor Structures for Logic Gates

(75) Inventors: Karl R. Erickson, Rochester, MN (US); Phil C. Paone, Rochester, MN (US); David P. Paulsen, Dodge Center, MN (US); John E. Sheets, II, Zumbrota, MN (US); Kelly L. Williams, Rochester, MN (US)

(73) Assignee: INTERNATIONAL BUSINESS MACHINES CORPORATION, Armonk, NY (US)

(21) Appl. No.: 12/793,118

(22) Filed: Jun. 3, 2010

(51) Int. Cl. H01L 27/088; H01L 21/8234

(52) U.S. Cl. 257/368; 438/279; 257/E27.06; 257/E21.616

(57) ABSTRACT

A vertical structure is formed upon a semiconductor substrate. The vertical structure comprises four dielectric layers parallel to a top surface of the semiconductor substrate and three conducting layers, one conducting layer between each vertically adjacent dielectric layer. A first FET (field effect transistor) and a third FET are arranged parallel to the top surface of the semiconductor and a second FET is arranged orthogonal to the top surface of the semiconductor. All three FETs are independently controllable. The first conducting layer is a gate electrode of the first FET; the second conducting layer is a gate electrode of the second FET, and the third conducting layer is the gate electrode of the third FET.

### FIELD OF THE INVENTION

This invention relates generally to Field Effect Transistors (FETs), and more particularly to vertically stacked FETs suitable for logic gate (e.g., NAND, NOR, AOI, OAI) configurations.

### SUMMARY OF EMBODIMENTS OF THE INVENTION

Semiconductor chips are expensive to manufacture. Therefore, it is important to place as much function as possible on a semiconductor chip of a given size. Engineers constantly strive to place logic gates as densely as possible. Embodiments of the current invention vertically stack Field Effect Transistors (FETs) in order to improve density. In particular, embodiments of the invention provide for stacking N-channel Field Effect Transistors (NFETs) and for stacking P-channel Field Effect Transistors (PFETs). The NFETs are independently controllable and can be used for an NFET portion of a NAND circuit, an AOI circuit or a NOR circuit. Likewise, the PFETs are independently controllable and can be used for a PFET portion of a NAND circuit or a NOR circuit. Conventional Complementary Metal Oxide Semiconductor (CMOS) logic has NFETs arranged side-by-side and PFETs also arranged side-by-side.

Vertically stacked FETs are constructed on a semiconductor substrate. A first FET on the semiconductor substrate has a first source, a first drain, a first gate dielectric, a first body, and a first gate electrode. A second FET has a second source, a second drain, a second gate dielectric, a second body, and a second gate electrode. A third FET has a third drain, a third source, a third gate electrode, a third gate dielectric, and a third body. The second FET is oriented orthogonally to the first and third FET, but on the same vertical stack, that is, on a side of the stack. The first, second, and third gate electrodes may be connected to different logical signals.

### BRIEF DESCRIPTION OF THE DRAWINGS

FIG. 1 shows a stack having a silicon semiconductor substrate (P− silicon assumed). Alternating layers of dielectric material (HfO₂ used for exemplary purposes) and FET gate conductor material (“metal” used for exemplary purposes) are depicted.

FIG. 2 shows a vertical structure etched from the stack of FIG. 1, in isometric style, further showing a gate area is formed on the vertical stack. The vertical structure is shown having “dogbone” ends suitable for etching and forming contacts with the FET gate electrodes.

FIG. 3 shows the vertical structure of FIG. 2 further covered in silicon dioxide.

FIG. 4 shows the silicon dioxide of FIG. 3 etched to expose a top of a top dielectric layer (HfO₂). A cross section AA is shown; cross section AA will be used in subsequent figures to show creation of FET devices.

FIG. 5 shows the cross section AA identified in FIG. 4. A dielectric (SiO₂ shown) spacer has been conformally deposited.

FIG. 6 shows the spacer after an anisotropic etch. Source and drain areas have been implanted.

FIG. 7 shows a first growth of an epitaxial layer. The doping of the first epitaxial layer is similar to the doping of the source and drain area (i.e., if the source and drain areas are N+, then the first epitaxial layer is also N+).

FIG. 8 shows an oxygen implant that creates an SiO₂ layer isolating a source (or drain) area from the first growth of epitaxial layer. A photoresist layer may be used to prevent SiO₂ formation over another source (or drain) area, as shown.

FIG. 9 shows the structure of FIG. 8 with photoresist removed. SiO₂ has been etched above the epitaxial area. A high-K dielectric (HfO₂ used for example) has been conformally deposited.

FIG. 10 shows the structure of FIG. 9 after anisotropic etching of the high-K dielectric and growth of a second epitaxial layer of opposite doping to the first epitaxial layer.

FIG. 11 shows the structure of FIG. 10 after further addition of a third epitaxial layer of similar doping to the first epitaxial layer and a fourth epitaxial layer of similar doping to the second epitaxial layer.

FIG. 12 shows the hole of FIG. 11 after planarization.

FIG. 13 shows structure of FIG. 12 after creation of a lined contact and contacts made to an exposed surface of the third epitaxial layer.

FIG. 14A shows a top view of the structure of FIG. 13 to show contacts made to source and drain regions and to gate electrodes. FIG. 14B shows a side view to illustrate a “stair step” arrangement to contact gate electrodes.

FIG. 15 shows, schematically, three NFETs connected in series.

FIG. 16 shows schematically two NFETs in series and another NFET connected in parallel with the series connected two NFETs.

FIG. 17 shows three NFETs connected in parallel.

FIG. 18 shows an embodiment of the invention wherein PFETs are created and connected in series.

### DETAILED DESCRIPTION OF THE EMBODIMENTS

In the following detailed description of embodiments of the invention, reference is made to the accompanying drawings, which form a part hereof, and within which are shown by way of illustration specific embodiments by which the invention may be practiced. It is to be understood that other embodiments may be utilized and structural changes may be made without departing from the scope of the invention.

Embodiments of the present invention provide for vertical structures of field effect transistors suitable for NAND NOR, and AOI logic gates. Detailed drawings and description are given for construction of N-channel Field Effect Transistors (NFETs); however, it will be clear that a similar process, with appropriate dopings, will create analogous PFET (P-channel Field Effect Transistors).

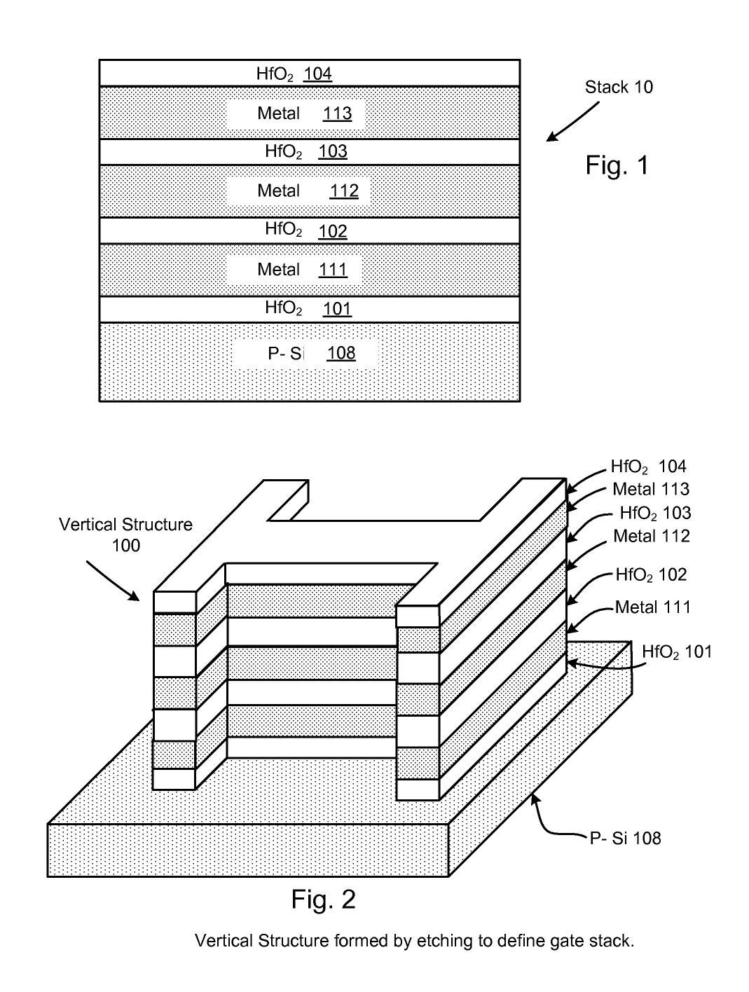

With reference now to FIG. 1, a stack 10 comprises a silicon substrate 108, shown as being doped P−, which forms a substrate for further processing of NFET transistors as will be explained below. It is understood that PFET transistors may be formed above an N− doped region, for example, an N-well in the silicon substrate 108. Alternating layers of a dielectric material (HfO₂ shown for exemplary purposes) and conducting material suitable for gate electrode material (e.g., metal or polysilicon; “metal” used for exemplary purposes) are stacked above silicon substrate 108. HfO₂ 101, 102, 103, and 104 are shown in FIG. 1 as the dielectric layers. Metal 111 is layered between HfO₂ 101 and HfO₂ 102; Metal 112 is layered between HfO₂ 102 and HfO₂ 103. Metal 113 is layered between HfO₂ 103 and HfO₂ 104. HfO₂ 101 and HfO₂ 104 will form gate dielectrics for a first and a third NFET and therefore need to be of appropriate thickness for gate dielectric purposes. HfO₂ 102 and HfO₂103 electrically isolate metal 111 from metal 112 and metal 112 from metal 113, respectively, and need to be of appropriate thickness for this purpose.

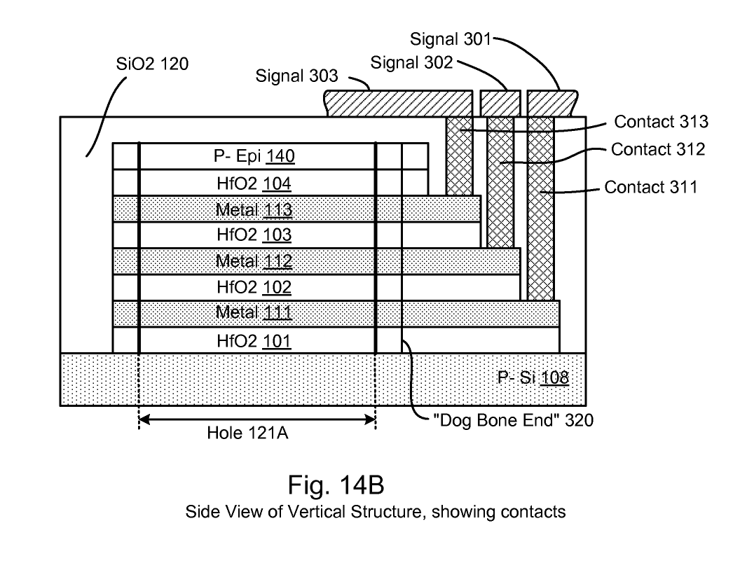

FIG. 2 shows stack 10 after processing in a semiconductor fabrication facility to produce a vertical structure 100. Vertical structure 100 is shown as having a “dog bone” shape. A middle area of vertical structure 100 is an area in which NFETs will be created. In the “dog bone” ends of vertical structure 100, the orthogonal areas (portions) at the ends are for contacting the gate electrodes (metals 111, 112, 113). Although shown where all “dog bone” ends are vertically aligned, vertical structure 100 may have, e.g., lower levels extending further to facilitate contacting as shown in FIG. 14A and FIG. 14B. The relatively wider, orthogonal, portions of the “dog bones” may provide space for dual contacts. Shapes other than “dog bones” are contemplated for dual contacts, for example, an “L” shape having a portion long enough to have a dual contact. An “L” having a shorter portion may be used if only a single contact is allowed in a particular technology. “Dog bone” ends need not be created at both ends of vertical structure 100. “Dog bones” may not be needed at all if metals 111, 112, and 113 are routed on those metal levels to signal sources desired for logical control (i.e., turning on/off) of the NFETs created. For example, metal 111 (or metal 112, 113), during processing in creation of vertical stack 100, may be routed to such a signal source and therefore a “dog bone” and vias to metal 111, 112, 113 are not required.

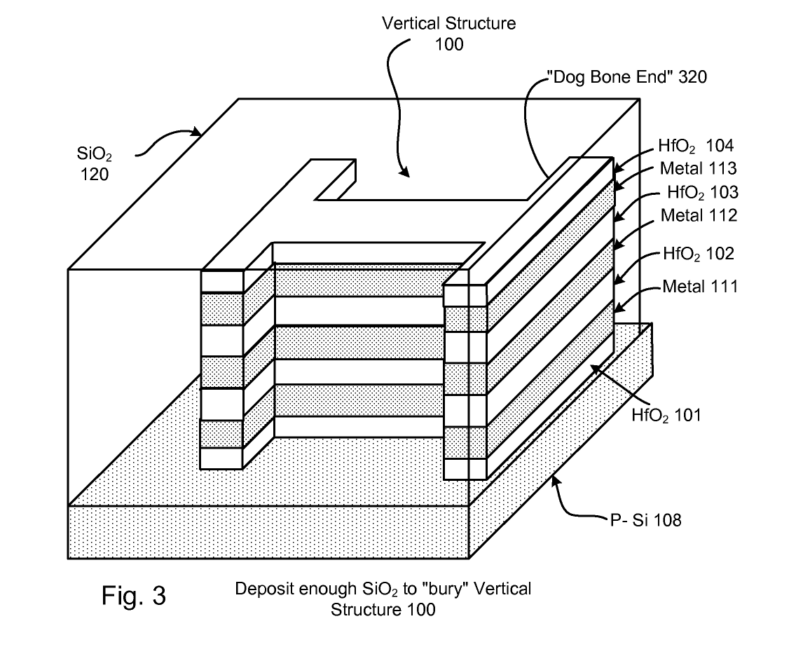

FIG. 3 shows the vertical structure 100 after further deposition of SIO₂ 120, or other suitable dielectric material, to cover vertical structure 100. A “dog bone end” 320 is depicted. “Dog bone end” 320 is an end of a portion of vertical structure 100 suitable for making one or more contacts, as will be further described with reference to FIGS. 14A and 14B.

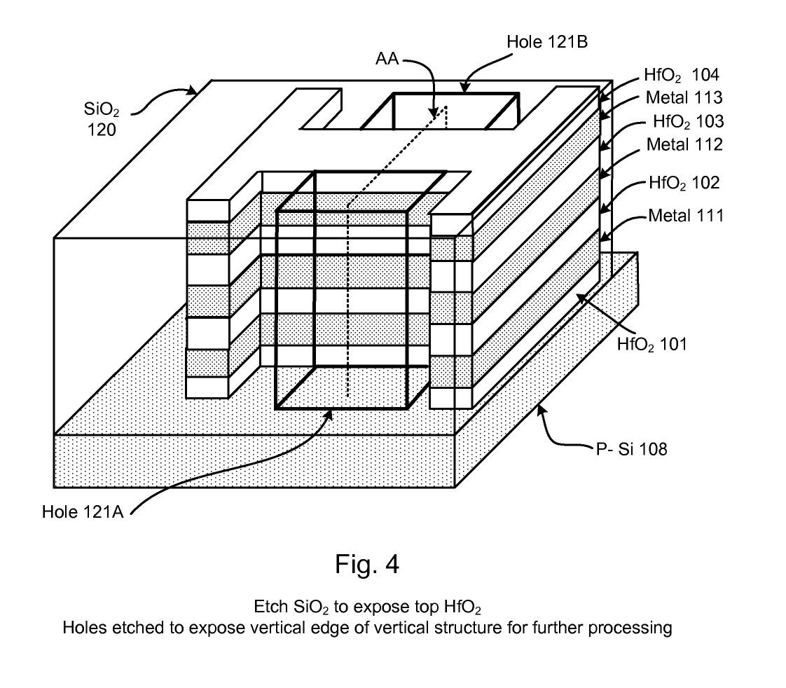

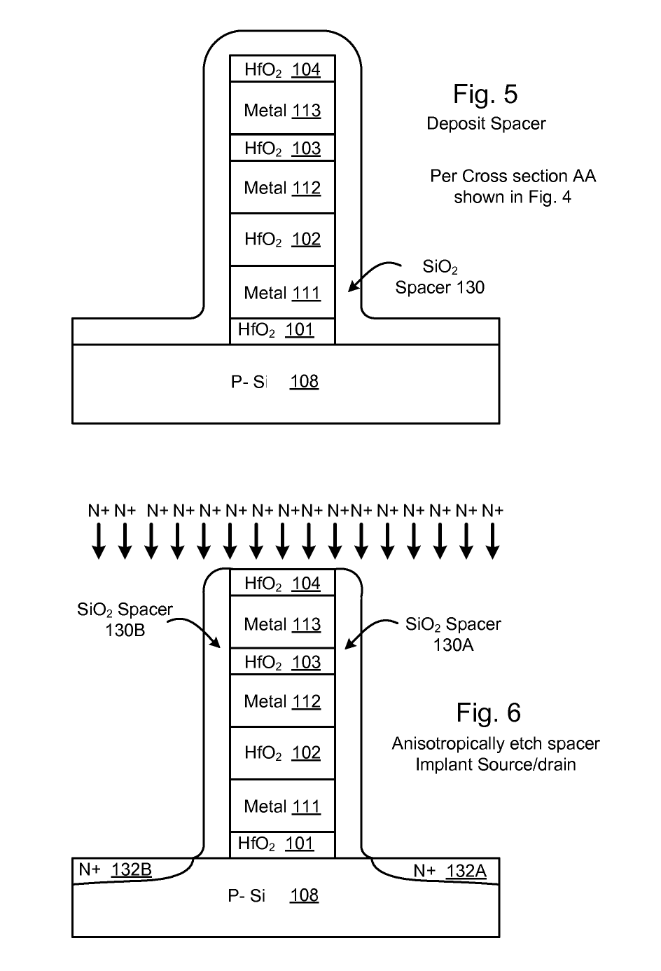

FIG. 4 shows the vertical structure 100 of FIG. 3 after etching SiO₂ 120 until a top surface of HfO₂ 104 is exposed. Holes 121A and 121B (generically, “holes 121”) are etched in order to expose vertical surfaces of vertical structure 100 for subsequent processing as will be described. FIG. 4 shows cross section AA which will be used in following figures. Cross section AA cuts through vertical structure 100 and holes 121 as depicted.

FIG. 5 shows the structure of FIG. 4 at cross section AA, after conformal deposition of a SiO₂ spacer 130.

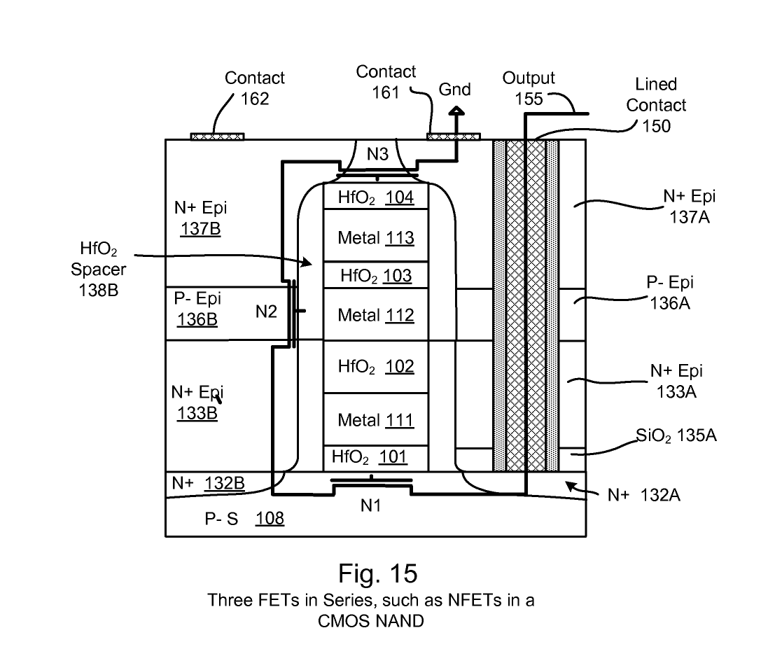

FIG. 6 shows the structure of FIG. 5 following an anisotropic etch of SiO₂ spacer 130. The anisotropic etch bares a top surface of HfO₂ 104 and a top surface of P− Si 108. Source/drain regions 132 (132A, 132B) are implanted into P− Si 108. At this stage of the process, source/drain regions 132 are the source/drains of a first NFET (See NFET N1 in FIG. 15); HfO₂ 101 is a gate dielectric of the first NFET; metal 111 is a gate electrode of the first NFET. For NFETs, source/drain regions 132 are also called N+ 132 for simplicity.

Source/drain regions 132A and 132B are created by the same implant processing step and are generically called source/drain regions 132. However, for clarity as to which source/drain region is intended, a suffix “A” is appended to 132 for the “right side” (in the drawing) source/drain region 132, and a suffix “B” is appended to 132 for the “left side” source/drain region 132. A similar convention is used hereinafter to designate “left side” and “right side” portions of a particular element.

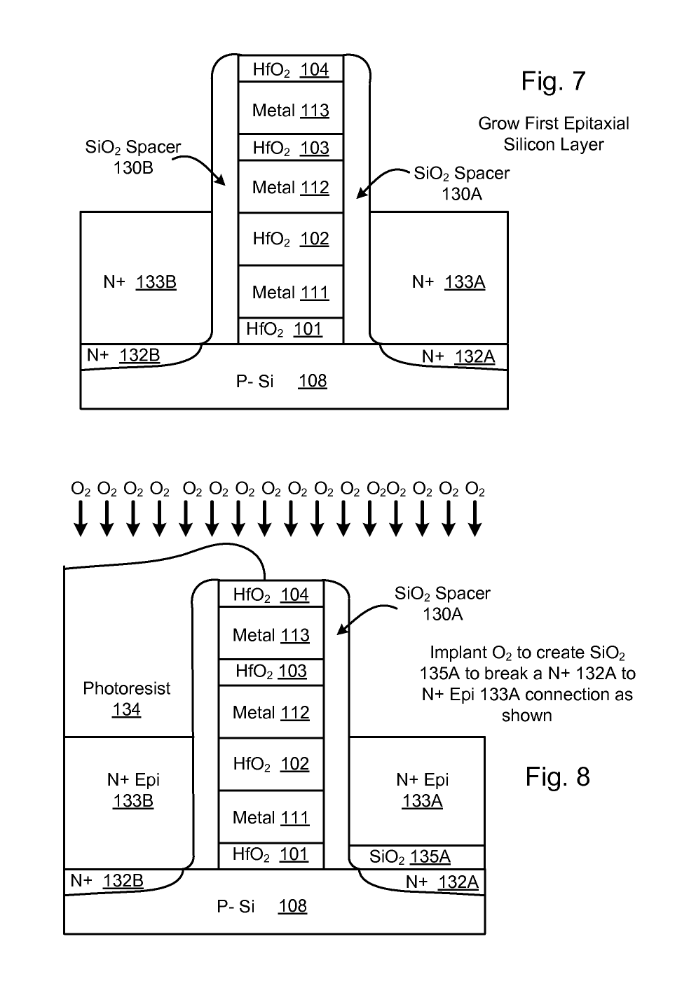

FIG. 7 shows the structure of FIG. 6 with addition of a first epitaxial growth, N+ Epi 133 (133A, 133B), grown over source/drain regions 132. Note the “right hand” and “left hand” “A”, “B” suffix convention. N+ Epi 133 has a doping similar to doping of source/drain regions 132. That is, if source/drain regions 132 are doped “N”, N+ Epi 133 is also doped “N”, with appropriate concentration of dopants.

While detail is given herein for creation of NFETs, it will be understood that PFETs may be created in a similar manner, for example starting with an N− Nwell in P− Si 108, P+ implantation forming source/drain regions for a PFET, and P+ epitaxial growth over source/drain regions of the PFET.

FIG. 8 shows the structure of FIG. 7 with addition of photoresist 134 and an oxygen implant of suitable energy to create SiO₂ 135A over source/drain region 132A. Photoresist 134 blocks the oxygen implant from forming a SiO₂ 135B over source/drain region 132B. SiO₂ 135A electrically isolates source/drain region 132A from an overlying N+ epi 133A. Source/drain region 132B remains in electrical connection with similarly doped overlying N+ epi 133B.

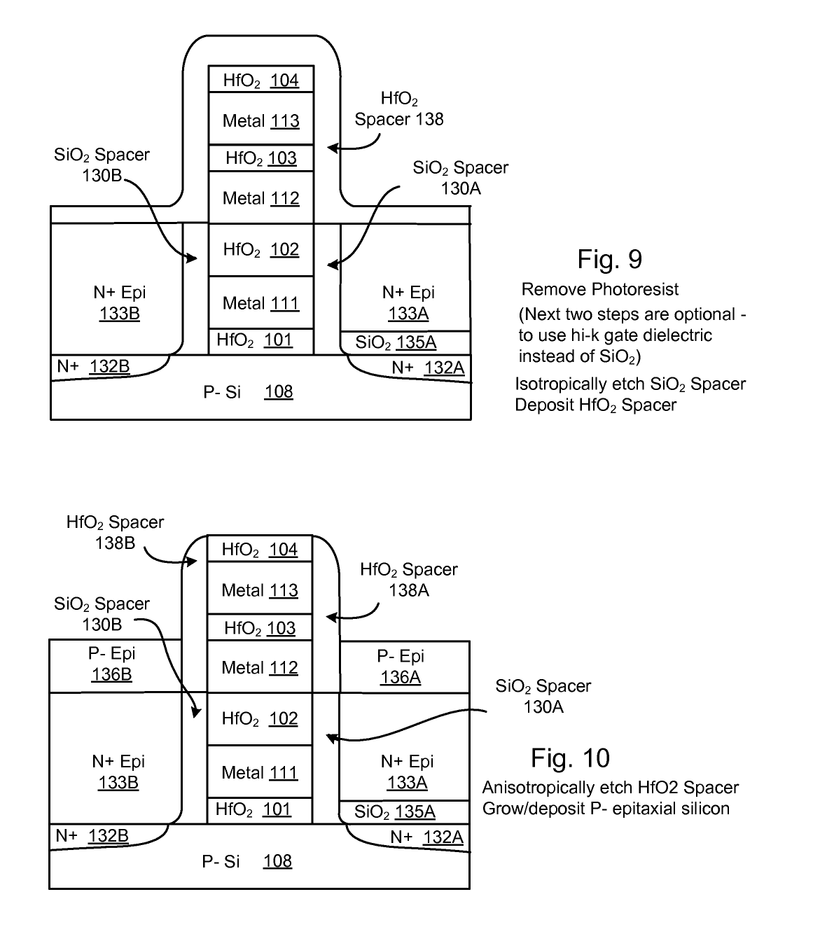

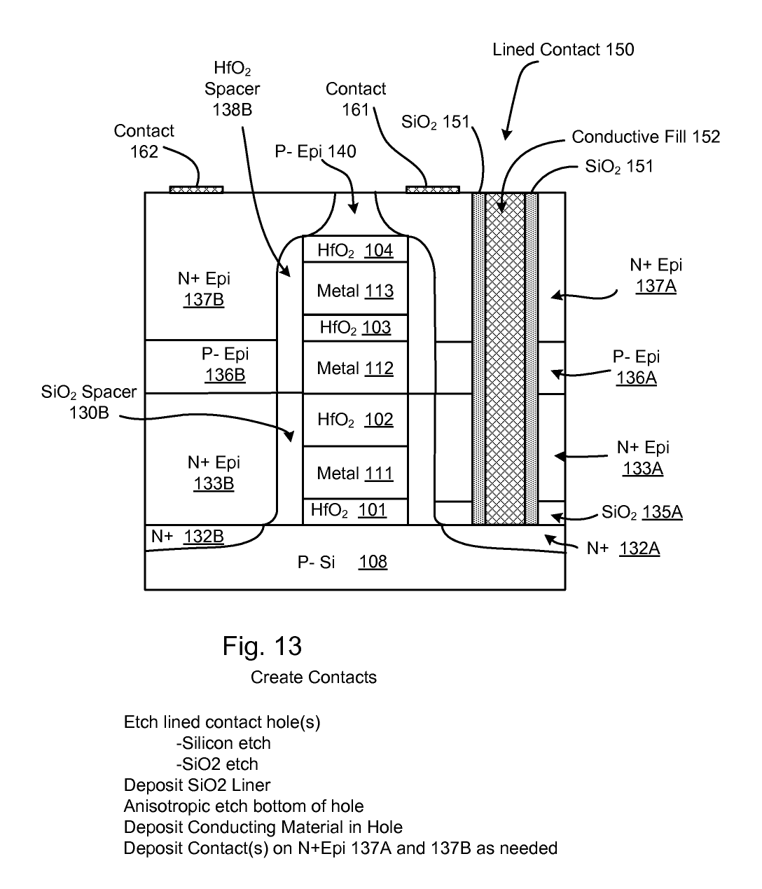

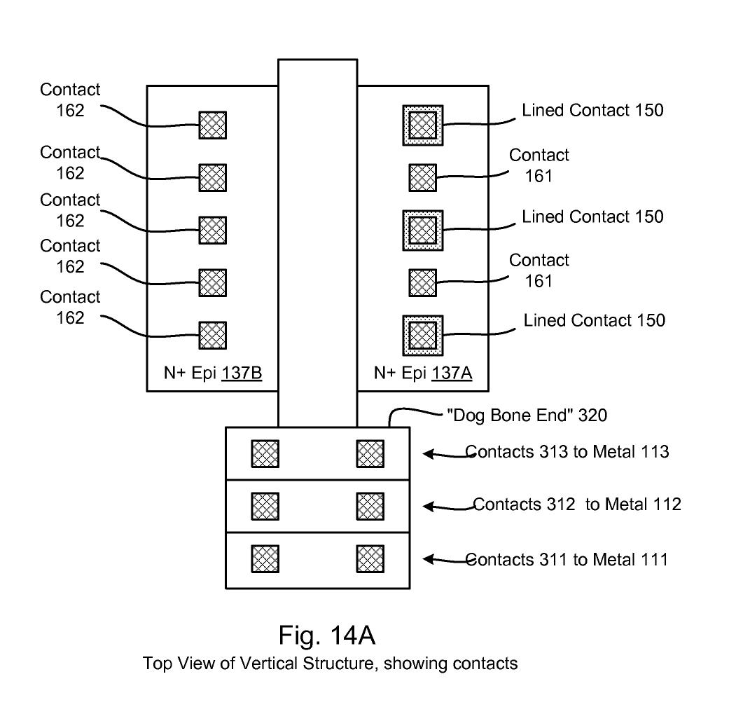

FIG. 9 shows the structure of FIG. 8 with removal of SiO₂ spacer 130 above HfO₂ 102, followed by addition of a conformal deposition of HfO₂ spacer 138. It is noted that removal of SiO2 spacer 130 may also etch a portion of SiO2 130 below a top surface of N+ Epi 132; however, that that occurs, the subsequent conformal deposition of HfO2 spacer 138 will fill in the portion removed. Note that, in an embodiment, this step is skipped, and SiO₂ spacer 130 is left intact. In this embodiment, gate dielectric for the second NFET (N2 in FIG. 13) will be SiO2 instead of HfO₂. HfO₂ is a modern high-K dielectric, and steps to provide HfO₂ as gate dielectric for N2 (FIG. 15) are therefore explained above.

FIG. 10 shows the structure of FIG. 9 following an anisotropic etch of HfO₂ spacer 138. Also, a second epitaxial growth, P− epi 136 (136A, 136B), is grown over N+ Epi 133 (133A, 133B). P− epi 136 is suitably doped to serve as a body of an NFET (N2 in FIG. 13). As with the previous step, this step may be skipped if SiO₂ spacer 130B is to be used as gate dielectric for N2 (FIG. 15).

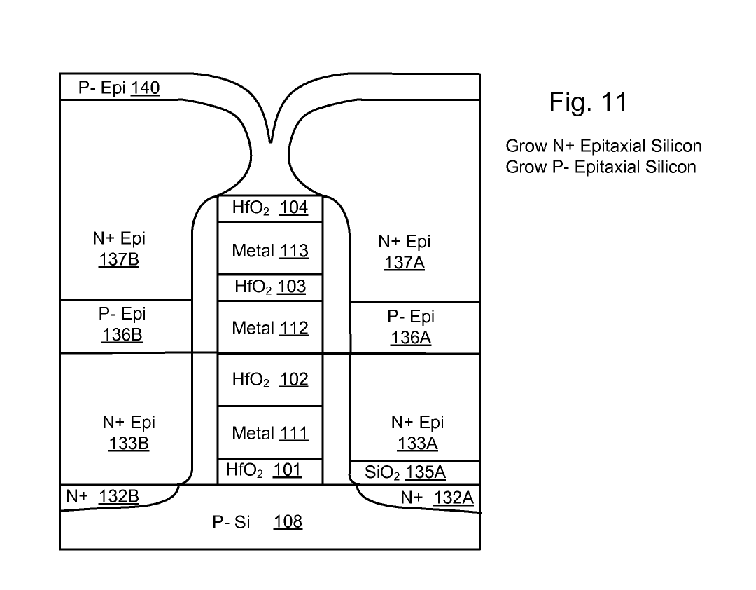

FIG. 11 shows the structure of FIG. 10 following growth of a third epitaxial growth, N+ Epi 137 (137A, 137B), over P− Epi 136. N+ Epi 137 is grown to a height that extends above a top of HfO₂ 104, and will “bulge” over HfO₂ 104 as depicted. A subsequent, fourth epitaxial growth, P− Epi 140 is grown over N+ Epi 137. P− Epi 140 is grown thick enough to completely cover HfO₂ 104 and is suitably doped to serve as a body of an NFET for which HfO₂ 104 serves as a gate dielectric.

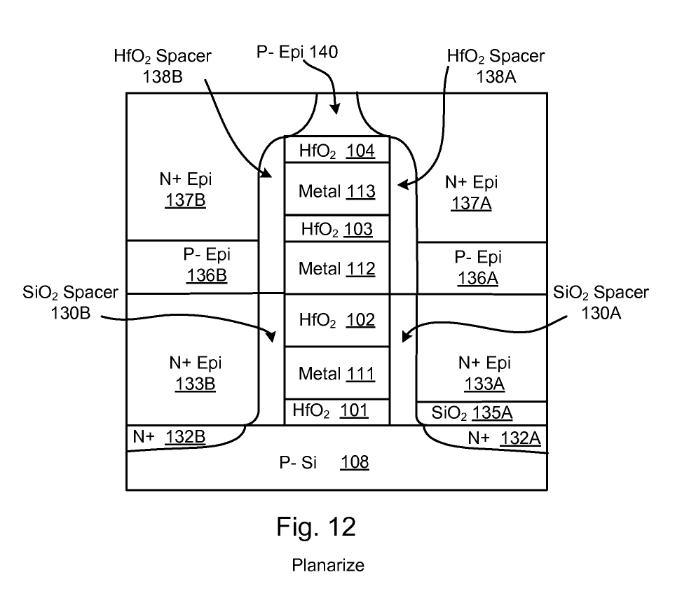

FIG. 12 shows the structure of FIG. 11, after planarization that removes P− Epi 140 except for a portion of P− Epi 140 above HfO₂ 104 and between N+ Epi 137A and N+ Epi 137B as shown.

FIG. 13 shows the structure of FIG. 12, including a lined contact 150 and contacts 161 and 162. Lined contact 150 is created by a silicon etch which etches through N+ Epi 137A, P− Epi 136A and N+ Epi 133A, followed by a SiO₂ etch through SiO₂ 135A to N+ 132A. A SiO₂ deposition leaves SiO₂ 151 around the sides and bottom of the hole created by the silicon etch and the SiO₂ etch. Then, an anisotropic etch removes the portion of the SiO₂ deposition at the bottom of the hole, exposing a portion of N+ 132A. A conductive fill 152, such as doped polysilicon or a metal such as tungsten, fills the hole and makes contact with N+ 132. Conductive fill is electrically isolated from N+ Epi 133A, P− Epi 136A, and N+ Epi 137A by SiO₂ 151. Contacts 161 and 162 are conventional contacts to top surfaces of N+ Epi 137A and N+ Epi 137B.

FIG. 14A shows a top view of the structure shown in FIG. 13. One or more contacts 162 are shown on the top surface of N+ Epi 137B. In FIG. 13, contact 161 was shown “closer to the center of the drawing” than lined contact 150, and, in an embodiment, contact 161 may be placed in such a position. However, to preserve space, in an embodiment, one or more contacts 161 may be alternated with lined contacts 150 as shown in FIG. 14A. In FIGS. 15, 16, 17, and 18, contacts 161 are shown as in FIG. 13 in order to clearly show electrical connections. FIG. 14A also shows one embodiment for electrically connecting to metals 111, 112, and 113. As shown, the “dog bone” portion of metal 111 extends beyond the “dog bone” portion of metal 112, which extends beyond the “dog bone” portion of metal 113. That is, metals 111, 112, and 113 are “stair stepped”. Etching through overlying material exposes the “dog bone” portions for making contacts (dual contacts are shown) to metal 111, 112 and 113. As explained earlier, if metal 112, 112, and/or 113 are routed on those metal levels to a source configured to logically drive the NFET gates created, no “dog bone” or contacts as shown are required. FIG. 14A shows “dog bone” ends at only one end of vertical structure 100.

FIG. 14B shows a side view of the structure shown in FIG. 13, to more clearly show the “stair step” contacting scheme shown in top view FIG. 14A. Contact 311 connects metal 111 to a signal 301 on a signal wiring level on a chip featuring the structure shown. Contact 312 connects metal 112 to a signal 302. Contact 313 connects metal 113 to a signal 303. Also shown is a “dog bone end” 320. SiO₂ 120 is shown surrounding the structure of FIG. 14B, and SiO₂ 120 is shown in FIG. 14B to include a SiO₂ area grown over the SiO₂ shown in FIG. 4; it is well-known to grow SiO₂ over devices for isolation from signal wiring layers. Hole 121A shows the portion of vertical structure 100 in which FET processing is accomplished. Hole 121A was also shown in FIG. 4. Contacts 311, 312, 313 are created with conventional etching techniques.

FIG. 15 shows the structure of FIG. 13, including an overlaid schematic of three NFETs (N1, N2, N3) connected in series, as they would be in a 3-way NAND logic circuit. A drain of N1 (N+ 132A) is connected through lined contact 150 (FIG. 13) to an output 155. A source of N1 (N+ 132B) is connected to a drain of N2 (N+ Epi 133B). A source of N2 (N+ Epi 137B) is also a drain of N3. A source of N3 (N+ Epi 137A) is connected to contact 161, which, as shown, is further connected to Gnd. Contact 162 in FIG. 15 is not used and may be omitted.

HfO₂101 is a gate dielectric of N1; metal 111 is a gate electrode of N1. P− Si 108 is a body of N1.

HfO₂ spacer 138B is a gate dielectric of N2. Metal 112 is a gate electrode of N2. P− Epi 138B is a body of N2.

HfO₂104 is a gate dielectric of N3; metal 113 is a gate electrode of N3; P− Epi 140 (FIG. 13) is a body of N3.

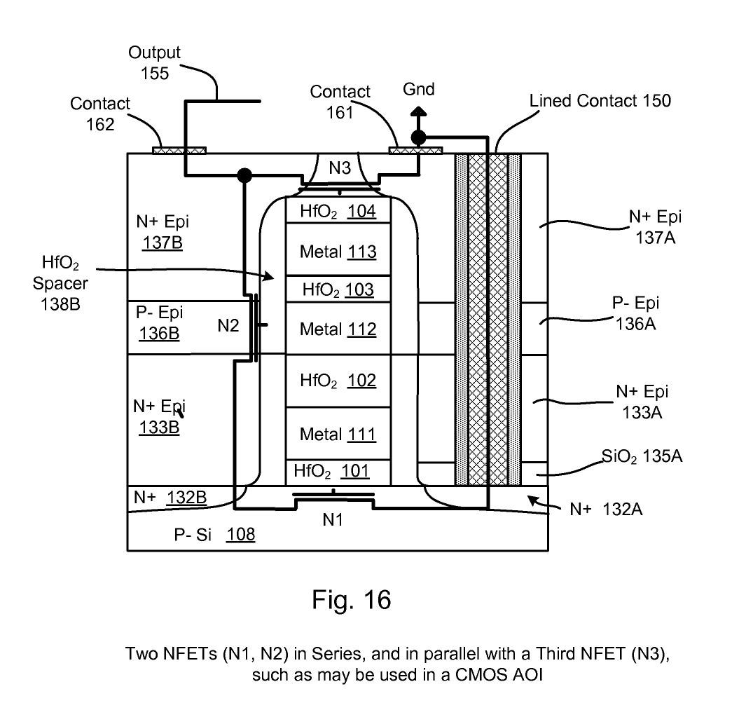

FIG. 16 shows the structure of FIG. 13 with three NFETs (N1, N2, N3) connected as NFETs may be in an AOI structure. N1 and N2 are connected in series between output 155 and Gnd as shown. N3 is connected between output 155 and Gnd as shown.

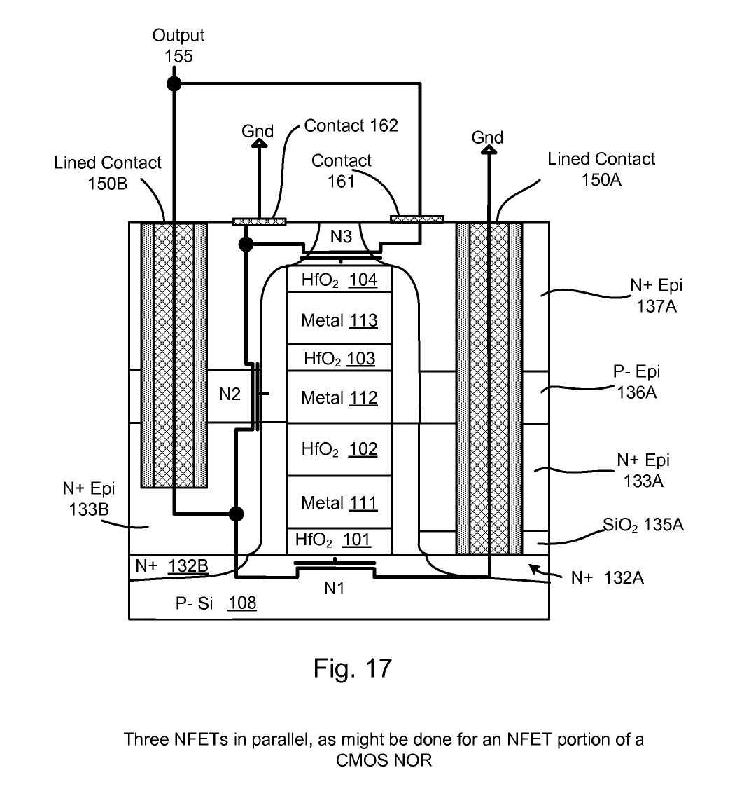

FIG. 17 shows the structure of FIG. 13, further comprising a lined contact 150B. N1, N2, and N3 are connected in parallel between output 155 and Gnd as shown. Lined contact 150B is created with a timed etch (no etch stop) to extend through N+ epi 137B, P− Epi 136B, and partway through N+ Epi 133B. An SiO₂ lining is deposited in a hole created by the timed etch, and the SiO₂ lining at a bottom portion of the hole is removed in an anisotropic etch, exposing a portion of N+ Epi 133B at the bottom of the hole. The hole is then filled with a conductive fill 152, as was done with conductive fill 152 (FIG. 13) in lined contact 150A. Drains of N1 and N2 (N+ 132B, N+ Epi 133B) are connected to output 155 through lined contact 150B. A drain of N3 (N+ Epi 137A) is connected to output 155 via contact 161. Sources of N2 and N3 (N+ 137B) are connected to Gnd through contact 162. A source of N1 (N+ 132A) is connected to Gnd through lined contact 150A.

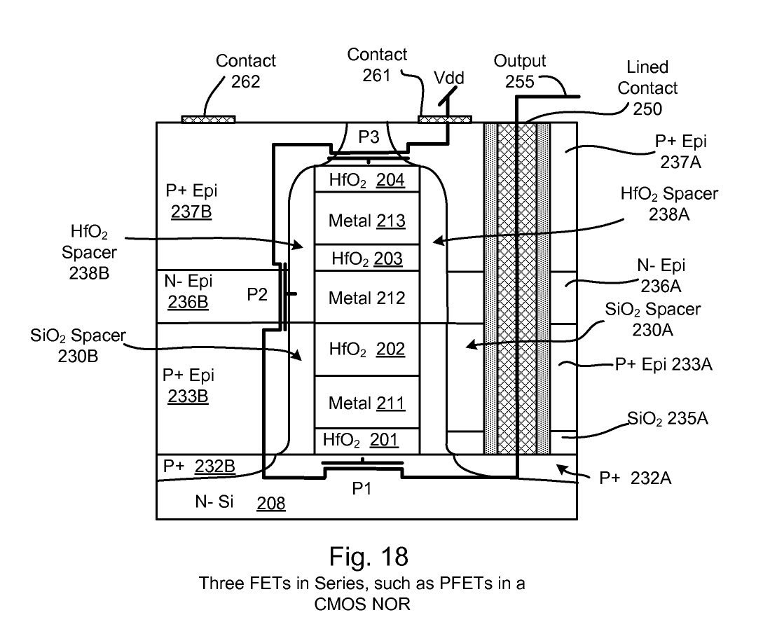

As mentioned earlier, PFETs may be created using the same techniques described in detail for NFETs, only with appropriate dopings. FIG. 18 shows three PFETs (P1, P2, P3) connected in series between Vdd and an output 255. Reference numbers are the same as used for NFETs, only are “200” numbers, rather than “100” numbers, for example HfO₂ 201 in FIG. 18 is analogous to HfO₂ 101 in, e.g., FIG. 16. In the case of the HfO₂ levels and metal levels in stack 100, the HfO₂ levels and metal levels are in fact the same as are shown for the NFET devices. Implants and growth of epi layers, however, are analogous, but doped differently, in order to produce PFETs.

In FIG. 18, a source (P+ Epi 237A) of P3 is connected to Vdd at contact 261. A drain of P3 (P+ Epi 237B) is connected to a source of P2 (also P+ Epi 237B). A drain of P2 (P+ Epi 233B) is connected to a source of P1 (P+ 232B). A drain of P1 (P+ 232A) is connected through lined contact 250 to an output 255. Other PFET connects suitable for NAND CMOS logic gates or AOI logic gates may be connected using the techniques taught with respect to NFETs earlier.

What is claimed is:

1. An apparatus comprising:
a semiconductor substrate;
a vertical structure on the semiconductor substrate having a first field effect transistor (FET), a second FET, and a third FET formed thereon, the second FET orthogonal to the first and third FET, the first, second, and third FETs configured to be independently controllable.

2. The apparatus of claim 1, wherein the vertical structure comprises:
a first dielectric layer; a second dielectric layer; a third dielectric layer; and a fourth dielectric layer;
a first conductor layer between the first dielectric layer and the second dielectric layer; a second conductor layer between the second dielectric layer and the third dielectric layer; and a third conductor layer between the third dielectric layer and the fourth dielectric layer;
the first conductor layer being a gate electrode of the first FET;
the second conductor layer being a gate electrode of the second FET; and
the third conductor layer being a gate electrode of the third FET.

3. The apparatus of claim 2 further comprising
a fifth dielectric layer formed on a vertical surface of the vertical structure;
the fifth dielectric layer forming a gate dielectric for the second FET;
the first dielectric layer forming a gate dielectric for the first FET; and
the fourth dielectric layer forming a gate dielectric for the third FET.

4. The apparatus of claim 3, further comprising:
a first source/drain area and a second source drain area and a second source/drain area, the first source/drain area being a drain of the first FET and the second source/drain area being a source of the first FET; and
a first epitaxial layer grown over the first and second source/drain areas, the first epitaxial layer of similar doping to the first and second source/drain areas.

5. The apparatus of claim 4, further comprising an oxygen implant forming a silicon dioxide layer to isolate the first source/drain area from the first epitaxial growth.

6. The apparatus of claim 5, further comprising:
a second epitaxial layer grown over the first epitaxial growth, the second epitaxial layer having a doping opposite the doping of the first epitaxial area, the second epitaxial layer having a doping suitable for a body of the second FET.

7. The apparatus of claim 6, further comprising:
a third epitaxial layer grown over the second epitaxial layer, the third epitaxial layer having a doping similar to the first epitaxial layer, the third epitaxial layer grown extend above the fourth dielectric layer; and
a fourth epitaxial layer grown over the third epitaxial layer and covering a top surface of the fourth dielectric layer, the fourth epitaxial layer having a doping opposite the third epitaxial layer and suitable for a body of the third FET, the fourth epitaxial layer removed by a planarization process except for a portion of the fourth epitaxial layer above the fourth dielectric layer.

8. The apparatus of claim 7, wherein the first FET, the second FET, and the third FET are connected in series.

9. The apparatus of claim 7, wherein the first FET, the second FET, and the third FET are connected in parallel.

10. The apparatus of claim 7, wherein the first FET and the second FET are connected in series and the third FET is connected in parallel to the first FET and the second FET series connection.

11. The apparatus of claim 7, wherein the first FET is an N-Channel FET (NFET), the second FET is an NFET, and the third FET is an NFET.

12. The apparatus of claim 7, wherein the first FET is a P-Channel FET (PFET), the second FET is a PFET, and the third FET is a PFET.

13. A method comprising:
creating a vertical structure on a semiconductor substrate, the vertical structure further comprising a first dielectric layer; a first conductor layer; a second dielectric layer; a second conductor layer, a third dielectric layer, a third conductor layer, and a fourth dielectric layer, and a fifth dielectric layer on a vertical side of the vertical structure;
creating a first field effect transistor (FET) having a source and a drain in the semiconductor substrate;
creating a second FET orthogonal to the first FET, the second FET using the fifth dielectric layer as a gate dielectric, and using the second conductor layer as a gate electrode;
creating a third FET parallel to the first FET, the third FET using the fourth dielectric layer as a gate dielectric, and using the third conducting layer as a gate electrode.

14. The method of claim 13, further comprising connecting the first FET, the second FET, and the third FET in series.

15. The method of claim 13, further comprising connecting the first FET, the second FET, and the third FET in parallel.

16. The method of claim 13, further comprising making a series connection comprising the first FET and the second FET and further comprising connecting the third FET is parallel with the series connection.
